(19) United States
(12) Patent Application Publication
(10) Pub. No.: US 2026/0129772 A1
(43) Pub. Date: May 7, 2026

(54) LINKAGE MECHANISM AND LIFTING DEVICE CONTAINING THE SAME

(71) Applicant: Aivres Systems Inc., Fremont, CA (US)

(72) Inventor: Yen-Hsun LIN, New Taipei City (TW)

(73) Assignee: Aivres Systems Inc., Fremont, CA (US)

(21) Appl. No.: 19/436,045

(22) Filed: Dec. 30, 2025

(51) Int. Cl. H05K 5/02; H05K 7/14

(52) U.S. Cl. CPC H05K 5/0208; H05K 7/1487

(57) ABSTRACT

A first linkage mechanism and/or a second linkage mechanism are provided. The first linkage mechanism includes: a supporting component; a connecting unit; and a fixation base. The connecting unit includes a first linkage member movable between a lifted position and a retracted position. The first linkage member includes a first body portion to connect with the fixation base. The first linkage member further includes a first end portion to connect with the supporting component. The first linkage member may further include a stop notch, and the fixation base may include a first protruding stopping element to engage with the stop notch of the first linkage member, so as to stop the first linkage member at the lifted position. The first and second linkage mechanisms may have mirrored structures, to form part of a lifting device.

### TECHNICAL FIELD

The present disclosure relates generally to a lifting device, and more particularly, to a linkage mechanism and a lifting device for storage enclosures or other systems.

### BACKGROUND

For an electronic or storage system like a server, an enclosure or a chassis is often provided to include or store multiple modules, such as storage module(s), power supply unit(s), cooling module(s), etc. Certain modules may be mounted (e.g., stacked within the chassis) such that it is difficult to access one or more of the multiple modules.

### SUMMARY

Techniques are described herein for a linkage mechanism or a lifting device having one or more linkage mechanisms (e.g., a first linkage mechanism and/or a second linkage mechanism). The first and second linkage mechanism may, or may not, have mirrored structures. The linkage mechanism (e.g., the first linkage mechanism or the second linkage mechanism) may include a first linkage member and/or a second linkage member. The second linkage member may be directly or indirectly coupled to the first linkage member. The linkage mechanism may further include a first group of stopping structures (e.g., a stopping shaft) that stops the first linkage member (and therefore the second linkage member) at a first position (e.g., a lifted position). The linkage mechanism may additionally or alternatively include a second group of stopping structures (one or more stopping members, which may be aligned with each other) to stop the first linkage member (and therefore the second linkage member) at a second position (e.g., a retracted position).

According to one aspect of the present disclosure, a linkage mechanism is provided. The linkage mechanism may include: a supporting component, a connecting unit, and/or a fixation base. The connecting unit may include a first linkage member movable between a lifted position and a retracted position. The first linkage member may include a first body portion to connect with the fixation base and a first end portion to connect with the first supporting component. In some embodiments, the first body portion of the first linkage member may be integrated with the first end portion of the first linkage member to form approximately an L shape.

In some embodiments, the fixation base includes a first protruding stopping element (e.g., the aforementioned stopping shaft) to stop the first linkage member at the lifted position. In some embodiments, the first body portion of the first linkage member may include a stop notch to engage with the first protruding stopping element. In some embodiments, the fixation base may include a plate region and a protruding region that protrudes from the plate region. In some embodiments, the first protruding stopping element that is configured to stop the first linkage member at the lifted position may be disposed on the protruding region of the fixation base.

In some embodiments, the fixation base may additionally, or alternatively, include one or more stopping members to stop the first linkage member at the retracted position. In some embodiments, the one or more stopping members may be disposed on the plate region of the fixation base.

In some embodiments, the supporting component may include an opening portion (shortly as “opening”) that provides access to a finger-grab portion of the supporting component.

In some embodiments, the fixation base may include a first protruding shaft member to engage with a first pivoting-connection hole that is at the first body portion of the first linkage member, thereby enabling the first body portion to be connected with the fixation base. In some embodiments, the first protruding shaft member may be disposed on the fixation base, e.g., in proximity to the first protruding stopping element.

In some embodiments, the connecting unit may include a second linkage member configured to move in response to the first linkage member being moved. In some embodiments, the second linkage member may include a second body portion and a second end portion. In some embodiments, the second body portion of the second linkage member may be integrated with the second end portion of the second linkage member to form approximately an L shape. As used in the present disclosure, the terms “approximately” or “substantially” are meant to cover any normal fluctuations or deviations (e.g., ±20% or other applicable deviation percentages or degrees) appreciated by one of ordinary skill in the relevant art.

In some embodiments, the fixation base may include a second protruding shaft member to engage with a second pivoting-connection hole that is at the second end portion of the second linkage member, thereby enabling the second end portion of the second linkage member to connect with the fixation base.

In some embodiments, the first body portion of the first linkage member is integrated with the first end portion of the first linkage member to form approximately an L shape.

In some embodiments, the first end portion of the first linkage member may include a first pivoting hole that corresponds to an installation hole at a first mounting plate of the supporting component.

In some embodiments, the supporting component may include the first mounting plate and a second mounting plate. In some embodiments, the second mounting plate may include an additional installation hole corresponding to the installation hole at the first mounting plate of the supporting component. In some embodiments, the additional installation hole at the second mounting plate may be smaller than the installation hole at the first mounting plate, to facilitate fastening of a fixation element (e.g., a screw) to the second mounting plate, where the fixation element may be applied to connect the supporting component with the connecting unit, e.g., through the aforementioned first pivoting hole, the installation hole, and/or the additional installation hole.

For example, the fixation element can be applied to traverse through the first pivoting hole at the first end portion of the first linkage member, the installation hole at the first mounting plate of the supporting component, the additional installation hole at the second mounting plate of the supporting component, to connect the supporting component with the first linkage member.

In some embodiments, the fixation element may be applied to further help secure a storage module (e.g., having one or more hard drive disks, “HDDs”) to the supporting component, e.g., through a mounting hole at a side plate/wall of the storage module as well as through the first pivoting hole, the installation hole, and the additional installation hole. For example, the fixation element can be applied to traverse through the first pivoting hole at the first end portion of the first linkage member, the installation hole at the first mounting plate of the supporting component, the additional installation hole at the second mounting plate of the supporting component, and the hole at the side wall of the storage module. In this way, not only is the supporting component connected with the first linkage member, but also the storage module is secured to the supporting component.

The linkage mechanism (or the lifting device) can be attached to a storage enclosure (e.g., a chassis for an electronic system such as a server), e.g., using one or more additional fixation elements. The configuration of the linkage mechanism according to one or more embodiments may allow convenient access to one or more components (e.g., one or more processors and/or one or more memory modules) stored within the storage enclosure (e.g., stacked below the storage module), without having to detach the linkage mechanism from the storage enclosure. For example, the linkage mechanism can be lifted to the lifted position, such that the storage module (e.g., having one or more HDDs) is lifted to expose the one or more components that would otherwise be stacked below the storage module, for access, repair, or replacement of the one or more component (or a portion thereof). The linkage mechanism may also be configured at the retracted position, such that the storage module is stored within the storage enclosure, and the storage enclosure can be, for instance, sealed or covered with a top cover.

In some embodiments, the linkage mechanism (e.g., the supporting component) may include a supporting shelf/seat capable of supporting the storage module (or any other applicable module or component for the electronic system). The storage module may be lifted in response to the linkage mechanism being lifted to the lifted position (or an intermediate position between the lifted position and the retracted position). In some embodiments, the storage module may be removably attached to the linkage mechanism. For example, the storage module may be lifted or removed to expose the one or more processors and/or one or more memory modules that are stored below the supporting shelf when the linkage mechanism is at the retracted position, thereby facilitating access to the one or more processors and/or one or more memory modules.

According to another aspect of the present disclosure, a lifting device is provided. The lifting device may include: a first linkage mechanism. The first linkage mechanism may include: a connecting unit, and a fixation base. In some embodiments, the connecting unit may include a first linkage member movable between a lifted position and a retracted position. In some embodiments, the first linkage member may include a first body portion to connect with the fixation base. In some embodiments, the first linkage mechanism may further include a supporting component. In some embodiments, the first linkage member includes a first end portion to connect with the supporting component.

In some embodiments, the lifting device may further include a second linkage mechanism. In some embodiments, the first and second linkage mechanisms may have mirrored structures.

According to a further aspect of the present disclosure, a linkage mechanism is provided. The linkage mechanism may include: a fixation base, and a first linkage member comprising a stop notch. In some embodiments, the fixation base may include a first protruding stopping element to engage with the stop notch of the first linkage member, so as to stop the first linkage member at a lifted position.

The foregoing is provided as an overview of only some embodiments of the present disclosure. These and other embodiments are disclosed in additional detail herein below. It is noted that a variety of other means and/or structures for performing the function and/or obtaining the results and/or one or more of the advantages described herein may be utilized. Each of such variations and/or modifications is deemed to be within the scope of the present disclosure. All parameters, dimensions, materials, and configurations described herein are meant to be exemplary and that the actual parameters, dimensions, materials, and/or configurations may depend upon the specific application or applications for which the teachings are used.

### BRIEF DESCRIPTION OF THE DRAWINGS

Systems and methods of the present disclosure are described in detail below with reference to the attached drawing figures, wherein:

FIG. 1 illustrates a block diagram of an example of a system according to one or more embodiments of the present disclosure.

FIG. 2A illustrates a diagram showing a mounting mechanism for mounting a storage module within a storage enclosure, according to one or more embodiments of the present disclosure.

FIG. 2B shows the storage module in FIG. 2A is mounted within the storage enclosure.

FIG. 3A illustrates a perspective view of a storage enclosure with a storage module at an unextended position, according to one or more embodiments of the present disclosure.

FIG. 3B illustrates a top view of the storage enclosure in FIG. 3A.

FIG. 3C illustrates a perspective view of the storage enclosure in FIG. 3A with the storage module at an extended position.

FIG. 3D illustrates a top view of the storage enclosure in FIG. 3C.

FIG. 3E illustrates an extending mechanism that mounts a storage module within a storage enclosure, according to one or more embodiments of the present disclosure.

FIG. 4A illustrates a perspective view of a first linkage mechanism in a first position, according to one or more embodiments of the present disclosure.

FIG. 4B illustrates a side view of the first linkage mechanism in FIG. 4A.

FIG. 4C illustrates an exploded view of the first linkage mechanism in FIG. 4A.

FIG. 4D illustrates a first perspective view of a supporting component of the first linkage mechanism in FIG. 4A.

FIG. 4E illustrates a second perspective view of the supporting component in FIG. 4A.

FIG. 4F illustrates a perspective view of a first linkage member in FIG. 4A.

FIG. 4G illustrates a perspective view of a fixation base in FIG. 4A.

FIG. 4H illustrates a perspective view of the first linkage mechanism in FIG. 4A in a second position.

FIG. 4I illustrates a side view of the first linkage mechanism in FIG. 4H.

FIG. 4J illustrates a perspective view of a lifting device having the first linkage mechanism in FIG. 4A in the first position.

FIG. 4K illustrates a perspective view of a lifting device having the first linkage mechanism in FIG. 4A in the second position.

FIG. 4L illustrates a top view of the lifting device with the first linkage mechanism in the first position and the second position, respectively.

FIG. 5A and FIG. 5B illustrate a process of mounting a lifting device for lifting a storage module, according to one or more embodiments of the present disclosure.

FIG. 6 illustrates a method for mounting a lifting device to lift a storage module from a chassis, according to one or more embodiments of the present disclosure.

FIG. 7 illustrates a method for assembling a lifting device, according to one or more embodiments of the present disclosure.

### DETAILED DESCRIPTION

The following detailed description is exemplary in nature and is not intended to limit the disclosure or the application and uses of the described embodiments. Furthermore, there is no intention to be bound by any expressed or implied theory presented in the preceding background, summary and brief description of the drawings, or the following detailed description. Numerous specific details are set forth in order to provide a more thorough understanding of the disclosed technology. However, it will be apparent to one of ordinary skill in the art that the disclosed technology may be practiced without these specific details. In other instances, well-known features have not been described in detail to avoid unnecessarily complicating the description.

An electronic or mechanical system (e.g., a server or a server system) often includes a storage enclosure. The storage enclosure, or a chassis included in the storage enclosure, stores (or otherwise includes) one or more power supply units (PSUs), one or more storage modules (e.g., each having one or more storage devices, such as hard disk drives “HDDs”), and/or other components or modules such as one or more cooling modules (e.g., fan(s) or liquid cooling unit(s)). Due to the limited space the storage enclosure or the chassis often possesses, certain components or modules of the electronic systems may be mounted (e.g., stacked) in a way that renders access to one or more of the components or modules (e.g., central processing unit “CPU,” memory module, etc.) rather difficult.

Systems, mechanisms, devices, and methods are disclosed herein that relate to facilitating access to (and/or maintenance of) one or more components or modules of an electronic or mechanical system (or other systems, such as a storage system) that are otherwise hard to access.

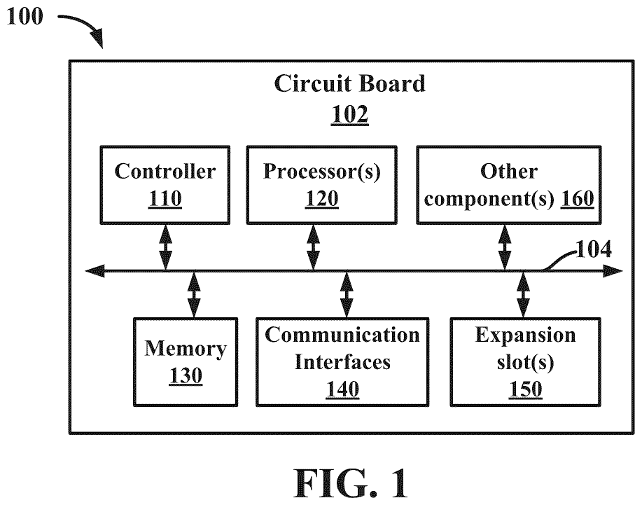

FIG. 1 illustrates a block diagram of a system 100, e.g., server, suitable for use in implementing embodiments of the present disclosure. It should be noted that the arrangements described herein, including this example, are provided for illustrative purposes only. Alternative configurations and components may be used in place of or in addition to those shown, and some components may be omitted entirely. Moreover, many of the elements described are functional in nature and can be implemented as standalone or distributed components or devices, either independently or in combination with other components, and located in various configurations. The functions discussed may be executed through hardware, firmware, and/or software, with processes typically performed by a processor running instructions stored in memory. Additionally, those skilled in the art will recognize that any system capable of performing the operations of the server system 100 falls within the scope and intent of the disclosed embodiments. The server system 100 can be housed in a rack-mounted chassis designed for optimal airflow and cooling, ensuring efficient heat dissipation during operation. Yet further, a person skilled in the art will recognize that the systems and methods described herein can be used with electronic systems and computer systems other than server systems.

The system 100 typically includes at least one circuit board 102, e.g., a motherboard, that may carry various components, including hardware, firmware, and/or software, which may be integrated with, attached to, connected to, or in communication with the motherboard. As shown in FIG. 1, the circuit board 102 carries at least one controller 110, such as a baseboard management controller (BMC), one or more processors 120, memory 130, communication interfaces 140, one or more expansion slots 150, and one or more other components 160. Such components and the circuit board 102 can communicate with one another through a bus 104, which may be integrated into the circuit board 102.

Processor(s) 120 may be configured to perform the operations in accordance with the computer-readable instructions stored in memory 130. In certain embodiments, the memory 130 may be integral to the processor(s) 120. In other embodiments, the memory may in whole or in part be separate from the processor(s) 120. Processor(s) 120 may include any appropriate type of general-purpose or special-purpose microprocessor or microcontroller (e.g., a central processing unit (CPU) or graphics processing unit (GPU), respectively), digital signal processor, microcontroller, or the like. Memory 130 may be configured to store computer-readable instructions that, when executed by processor(s) 120, can cause processor(s) 120 to perform various operations disclosed herein and/or store data relating thereto.

Memory 130 may be any non-transitory type of mass storage, such as volatile or non-volatile, magnetic, semiconductor-based, tape-based, optical, removable, non-removable, or other type of storage device or tangible computer-readable medium including, but not limited to, a read-only memory (“ROM”), an electrical erasable programmable ROM (EEPROM), a flash memory, a dynamic random-access memory (“RAM”), and/or a static RAM. In certain embodiments, memory 130 may include multiple storage devices of various types.

Communication interfaces 140 may be configured to communicate information between system 100 and other devices or systems. For example, communication interfaces 140 may include an integrated services digital network (“ISDN”) card, a cable modem, a satellite modem, or a modem to provide a data communication connection. As another example, communication interfaces 140 may include a local area network (“LAN”) card to provide a data communication connection to a compatible LAN. As a further example, communication interfaces 140 may include a high-speed network adapter such as a fiber optic network adaptor, 10G Ethernet adaptor, or the like. Wireless links can also be implemented by communication interfaces 140. In such an implementation, communication interfaces 140 can send and receive electrical, electromagnetic, or optical signals that carry digital data streams representing various types of information via a network. The network can typically include a cellular communication network, a Wireless Local Area Network (“WLAN”), a Wide Area Network (“WAN”), or the like.

Controller 110, e.g., BMC, may include a processing unit, associated memory, and communication interfaces, and is configured to monitor and manage the system's hardware components among other things. Controller 110 handles tasks such as remote system management, including hardware health monitoring, system event logging, and power control. Controller 110 can operate independently of the system's 100 main processor (e.g., processor(s) 120), allowing for out-of-band management. Controller 110 may in certain embodiments facilitate communication with various sensors (e.g., other component(s) 160) on the circuit board 102 to track temperature, fan speed, voltage levels, and other critical parameters. Additionally, the controller 110 may include network interfaces and/or operate in conjunction with communication interfaces 140 to enable remote access for system administrators, providing a way to perform diagnostic tasks, power cycling, and firmware updates.

The expansion slot(s) 150 on the circuit board 102 may be used for connecting additional peripherals, such as GPUs, network cards, and more.

The other components 160 can include integrated components, replaceable components, and other suitable components. For example, these components may include but are not limited to sensors, cooling modules/devices, power supply modules (and/or connectors), clock generators, chipsets, and more. In one or more embodiments, a chipset refers to a component or a group of components that manage communication between the CPU, memory (RAM), storage devices, network interfaces, and other peripherals.

It will be understood that the various components described in the foregoing description may be distributed amongst different circuit boards and/or may be included in different enclosures or subsystems of the system that may be removable during service and/or for other reasons.

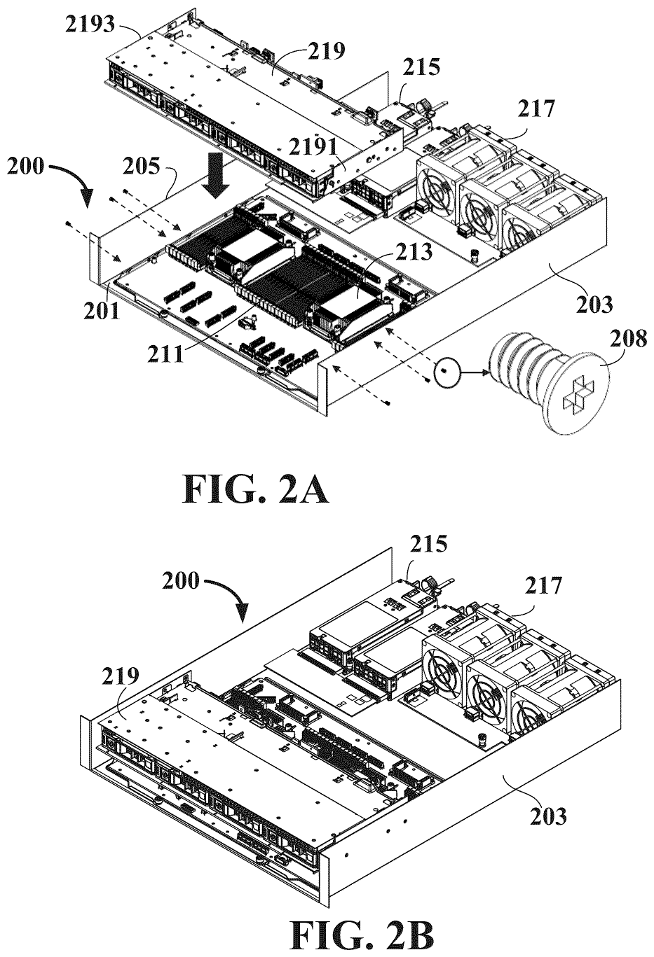

FIG. 2A illustrates a diagram showing a mounting mechanism for mounting a storage module within a storage enclosure, according to one or more embodiments of the present disclosure. FIG. 2B shows the storage module in FIG. 2A is mounted within the storage enclosure. As shown in FIG. 2A, a storage enclosure of an electronic system (or a storage system), such as a server, may include a chassis 200 made of one or more materials (e.g., steel or aluminum) that provide appropriate strength and rigidity. The chassis 200 may be configured to accommodate one or more components (or modules) of the electronic system. As a non-limiting example, referring to FIG. 2A, the chassis 200 may include a bottom portion 201 (e.g., a bottom plate) having one or more connector slots to receive one or more memory modules 211 (e.g., dual in-line memory module, “DIMM”), respectively. Additionally, or alternatively, the bottom portion 201 may be installed with one or more processing units 213 (e.g., CPUs, GPUs, neural processing units “NPUs”). Additionally, or alternatively, the chassis 200 may further accommodate one or more PSUs 215. Additionally, or alternatively, the chassis 200 may further accommodate one or more cooling units 217 (e.g., fan(s), or liquid cooling unit(s)).

Continuing with the non-limiting example above, the chassis 200 may further include a first side portion 203 (e.g., a first side plate), a second side portion 205 (e.g., a second side plate), a front portion (e.g., a front plate, not shown in FIG. 2A), a rear portion (e.g., a rear plate, not shown in FIG. 2A), and/or a top portion (e.g., a top cover or a top plate, not shown in FIG. 2A). In some embodiments, the chassis 200 may further include one or more additional hardware components, such as a storage module 219. The storage module 219 may include, for instance, one or more storage devices, such as one or more hard disk drives (HDDs) and/or solid-state drives (SSDs). In some embodiments, the storage module 219 may include a first side plate 2191 and a second side plate 2193.

Continuing with the non-limiting example above, the first side plate 2191 may include one or more mounting holes, and a first set of fixation elements (e.g., one or more screws 208) may be applied to attach (e.g., removably attach) the first side plate 2191 of the storage module 219 to the first side portion 203 of the chassis 200. The second side plate 2193 may include one or more mounting holes, and a second set of fixation elements (e.g., one or more screws) may be applied to attach (e.g., removably attach) the second side plate 2193 of the storage module 219 to the second side portion 205 of the chassis 200. The one or more mounting holes at the first side plate 2191 and the one or more mounting holes at the second side plate 2193 may form a mounting mechanism (or a part of the mounting mechanism) that mounts (or installs) the storage module 219 within the chassis 200.

Continuing with the non-limiting example above, the one or more memory modules 211 (and/or the one or more processing units 213) are installed or mounted prior to the storage module 219 being mounted. To access a memory module from the one or more memory module 211 (or to access a processing unit from the one or more processing units 213) for maintenance, removal, or replacement, the storage module 219 may be removed (e.g., detached from the chassis 200 by removing the aforementioned first and second sets of fixation elements) to expose the memory module to be accessed for maintenance, etc.

It is noted that, while FIG. 2A depicts a position of the storage module 219 prior to being mounted and FIG. 2B depicts a position of the storage module 219 after being mounted, the present disclosure is not limited to using the disclosed mounting mechanism to mount the storage module 219. In other words, any other applicable component may be mounted within the chassis 200 (or other structure) using the disclosed mounting mechanism.

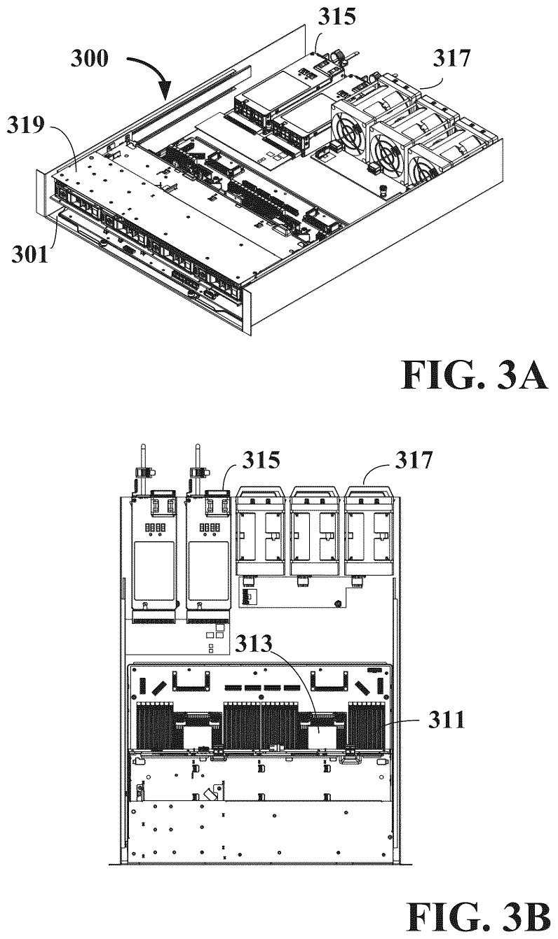

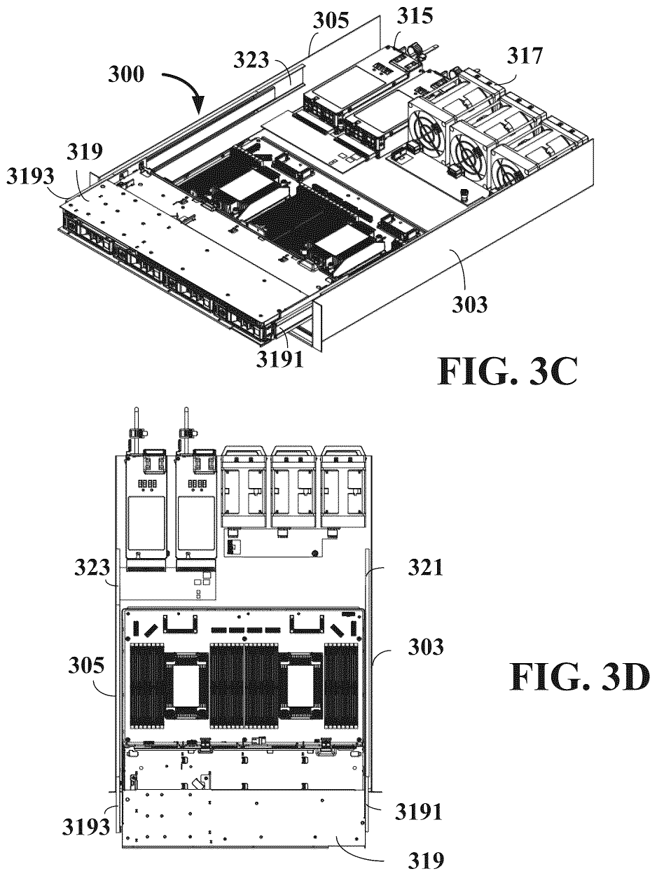

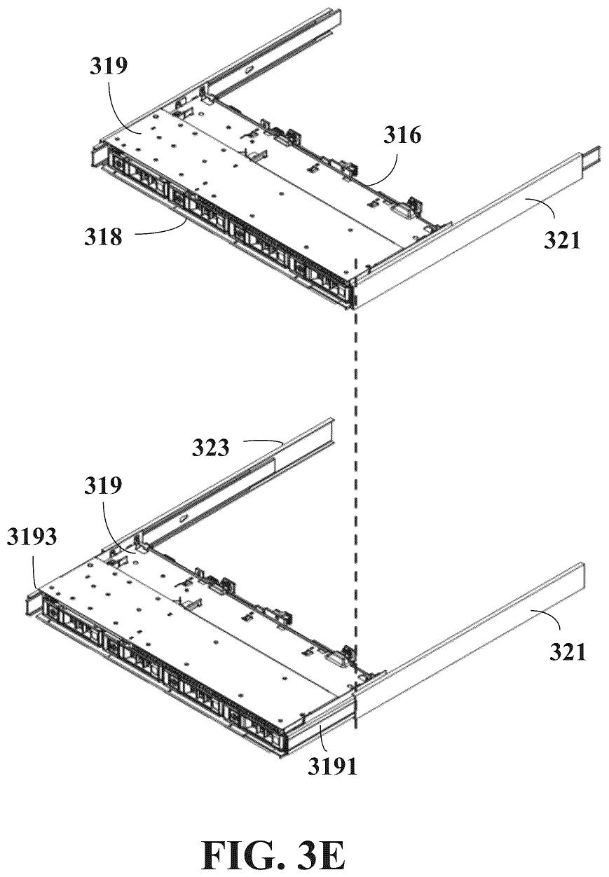

FIG. 3A, FIG. 3B, FIG. 3C, FIG. 3D, and FIG. 3E illustrate diagrams showing a storage enclosure with an extending mechanism according to one or more embodiments of the present disclosure. As shown in FIG. 3A˜3E, a storage enclosure of an electronic system (or a storage system), such as a server, may include a chassis 300. The chassis 300 may include a bottom portion 301 installed with one or more memory modules 311 (e.g., “DIMM”) and/or one or more processing units 313 (e.g., CPUs, GPUs, NPUs, etc.). The chassis 300 may further accommodate additional component(s) such as one or more PSUs 315, one or more cooling units 317, and/or a storage module 319. The storage module 319 may include a first side plate 3191 and a second side plate 3193. The storage module 319 (or the chassis 300) may further include an extending mechanism for the storage module 319 (or any other applicable module) to extend from (or be inserted into) the chassis 300. The extending mechanism (may also be referred to as “sliding mechanism”) may include, for instance, one or more rails that enable the storage module 319 to slide into or out of the chassis 300.

In some embodiments, the one or more rails may include a first guide rail 321 attached (e.g., fixedly attached or removably attached) to a first side portion 303 of the chassis 300. The one or more rails can further include the first side plate 3191 as a running rail. The first side plate 3191 of the storage module 319 may be engaged with the first guide rail 321. For example, the first side plate 3191 may be configured to move in a linear manner along a direction defined by the first guide rail 321.

Additionally, or alternatively, the one or more rails may include a second guide rail 323 attached (e.g., fixedly attached or removably attached) to a second side portion 305 of the chassis 300. The one or more rails can further include the second side plate 3193 as a running rail. The second side plate 3193 of the storage module 319 may be engaged with the second guide rail 323. For example, the second side plate 3193 may be configured to move in a linear manner along a direction defined by the second guide rail 323.

In some embodiments, by engaging the first side plate 3191 of the storage module 319 with the first guide rail 321 and by engaging the second side plate 3193 of the storage module 319 with the second guide rail 323, the extending mechanism allows the storage module 319 to extend from or be retractable into the chassis 300. In some embodiments, the extending mechanism may further include one or more rolling wheels (not depicted) to facilitate extension or sliding of the storage module 319. The one or more rolling wheels may, for instance, be attached (e.g., removably attached) to a bottom surface of the storage module 319.

In some embodiments, the one or more memory modules 311 (and/or the one or more processing units 313) may be installed or mounted prior to the storage module 319 being mounted. In some embodiments, the one or more memory modules 311 (and/or the one or more processing units 313) may be installed or accessed after the storage module 319 is mounted. For example, the storage module 319 may be pulled out of the chassis 300 using the disclosed extending mechanism, to expose space below the storage module 319, such that the one or more memory modules 311, the one or more processing units 313, other applicable components, or any combination thereof, can be exposed for ease of installation, access, maintenance, or replacement, etc.

In some embodiments, referring to FIG. 3E, the storage module 319 may include the first guide rail 321 and/or the second guide rail 323, where the first side plate 3191 engages with the first guide rail 321 and the second side plate 3193 engages with the second guide rail 323. A user may push a rear portion 316 of the storage module 319 for the storage module to extend from the chassis 300 (e.g., be stopped at an extended position, see FIG. 3C), which exposes components (e.g., memory module(s) 311 and/or processing unit(s) 313) that would otherwise be stacked below the storage module 319 when the storage module 319 is at a retracted/unextended position (see, e.g., FIG. 3A). This allows a user to access one or more components of the memory module(s) 311 and/or processing unit(s) 313, to maintain, remove, or replace one or more of the memory module(s) 311 and/or processing unit(s) 313. In some embodiments, a user may push a front portion 318 of the storage module 319 for the storage module 319 to slide back into the chassis (e.g., at the unextended position). For example, after replacing one of the memory modules 311, a user may push the front portion 318 of the storage module 319, to place the storage module 319 back at the unextended position.

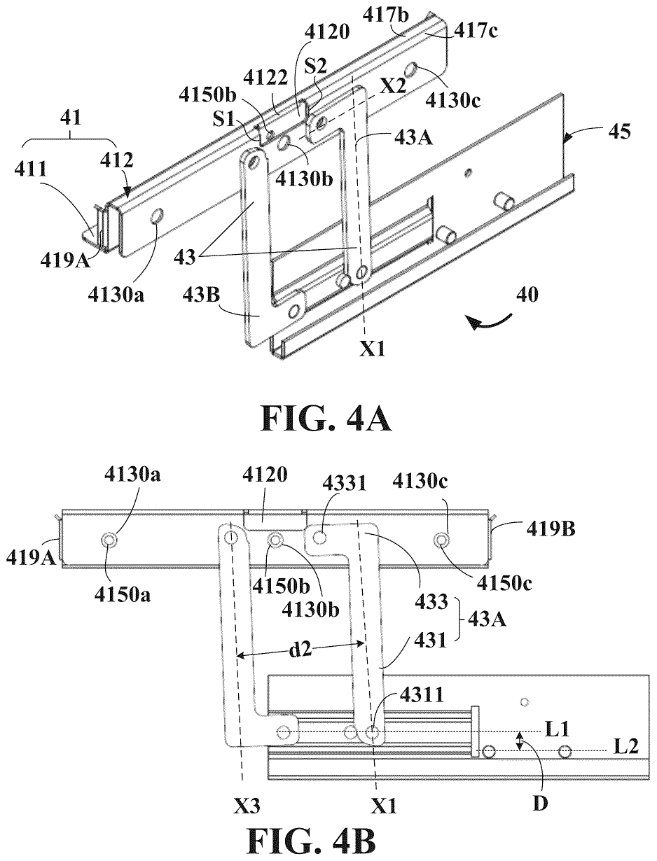

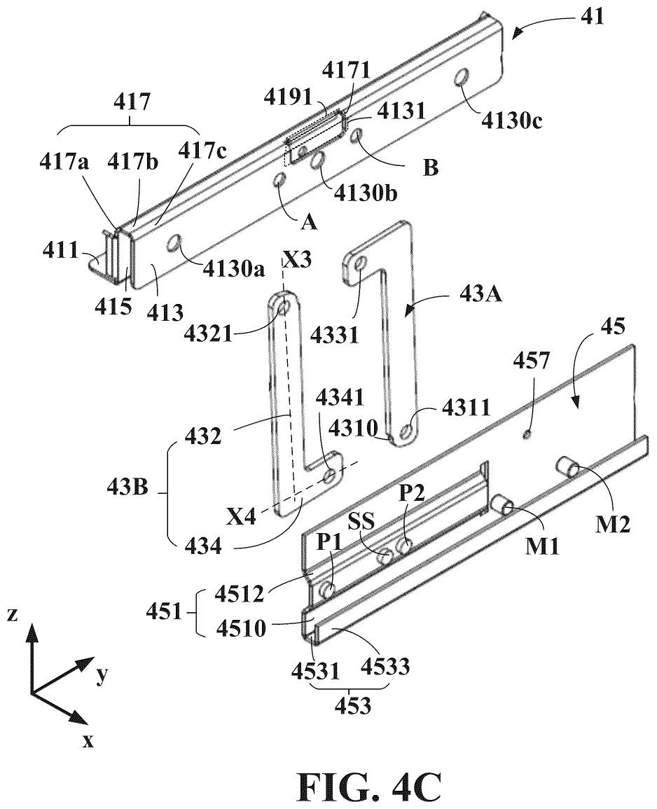

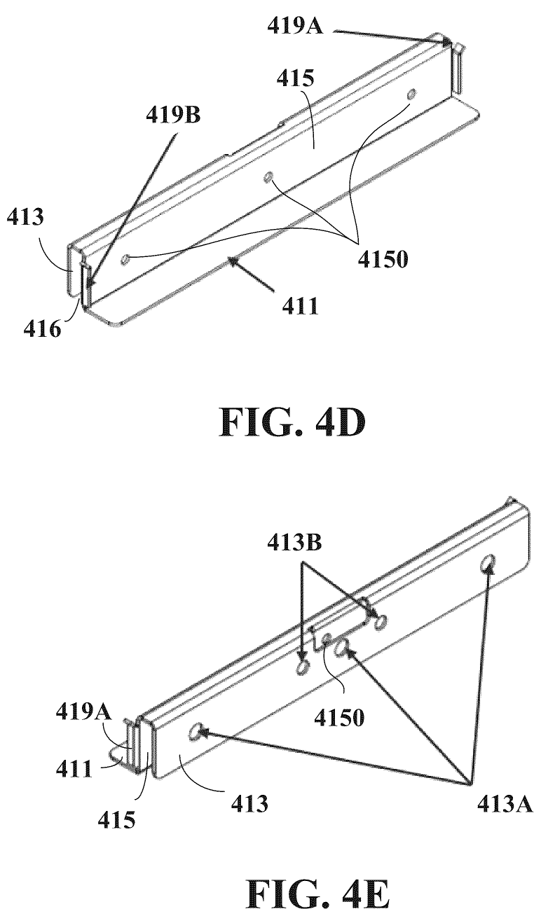

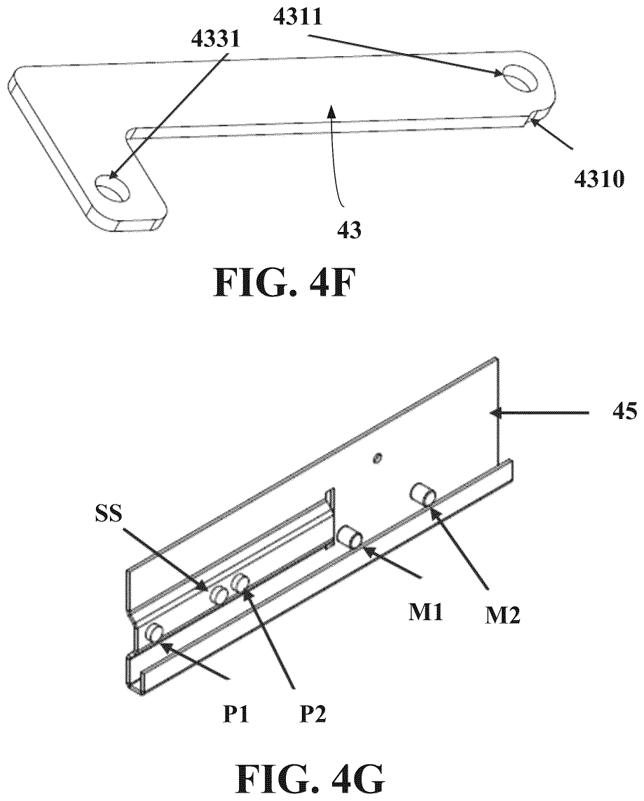

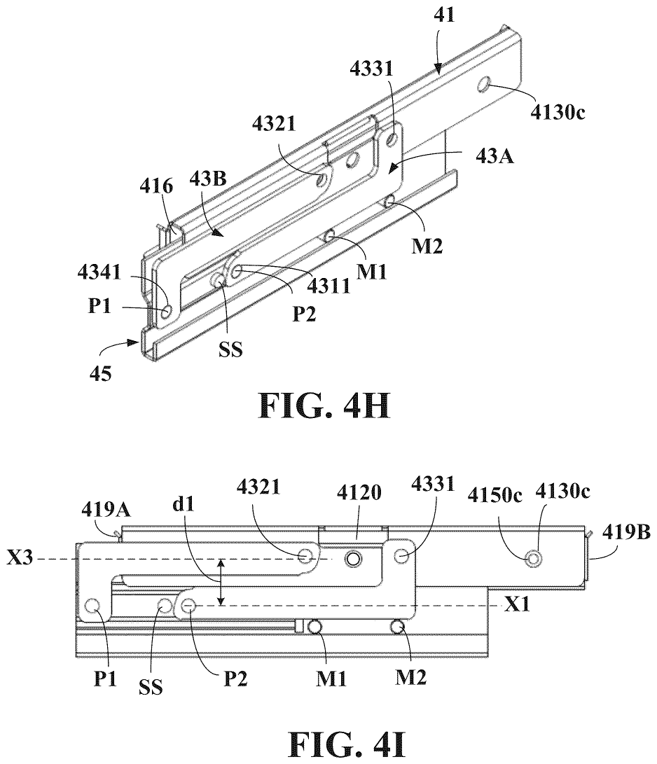

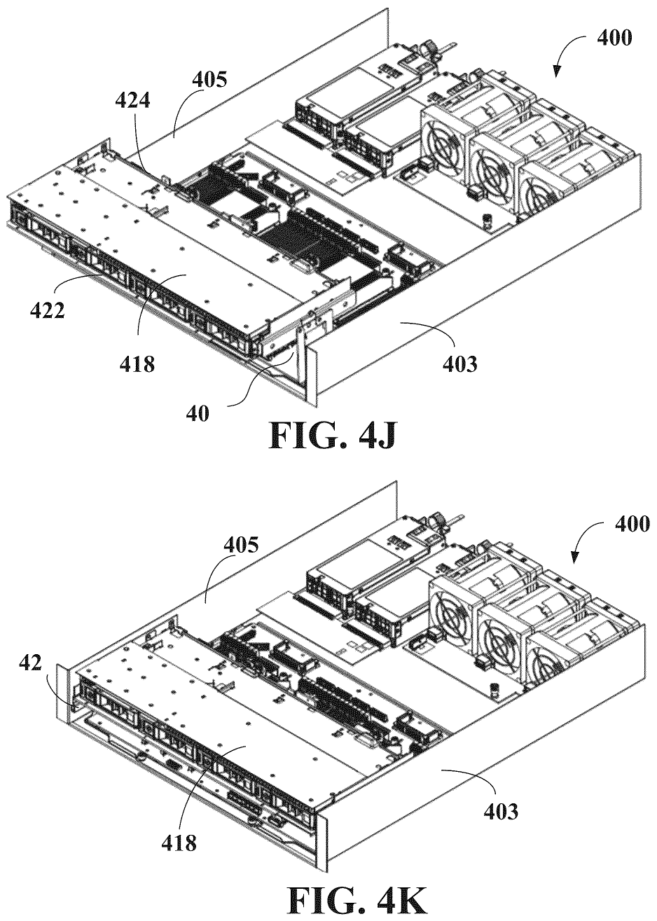

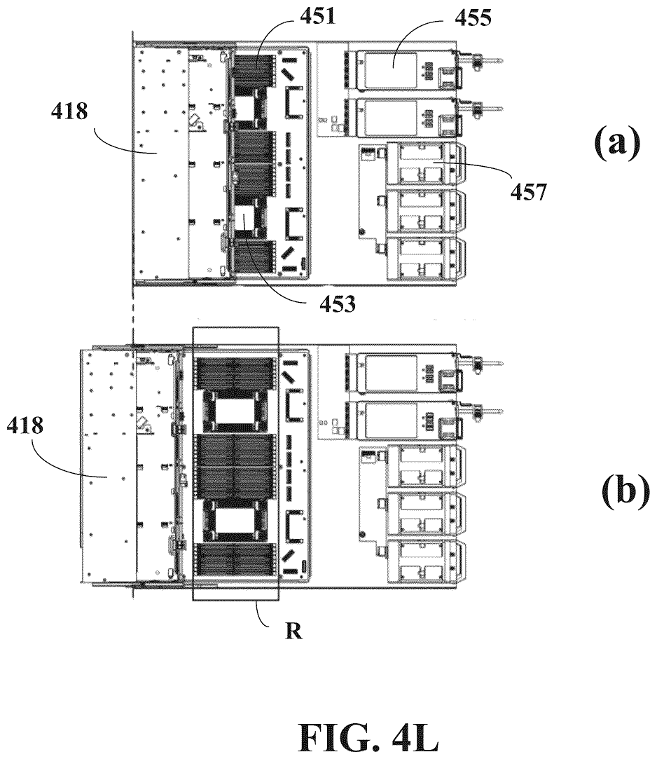

FIG. 4A illustrates a perspective view of a first linkage mechanism in a first position (e.g., a lifted position), according to one or more embodiments of the present disclosure. FIG. 4B illustrates a side view of the first linkage mechanism in FIG. 4A. FIG. 4C illustrates an exploded view of the first linkage mechanism in FIG. 4A. FIG. 4D illustrates a first perspective view of a supporting component of the first linkage mechanism in FIG. 4A. FIG. 4E illustrates a second perspective view of the supporting component in FIG. 4A. FIG. 4F illustrates a perspective view of a first linkage member in FIG. 4A. FIG. 4G illustrates a perspective view of a fixation base in FIG. 4A. FIG. 4H illustrates a perspective view of the first linkage mechanism in FIG. 4A in a second position (e.g., a retracted position). FIG. 4I illustrates a side view of the first linkage mechanism in FIG. 4H.

Referring to FIG. 4A and FIG. 4B, in some embodiments, a first linkage mechanism 40 may include a supporting component 41, a connecting unit 43, and a fixation base 45. The connecting unit 43 may include a first linkage member 43A (also referred to as a “driving linkage member” or “driving component”) and a second linkage member 43B (e.g., “auxiliary linkage member” or “auxiliary component”). In some embodiments, the supporting component 41 may include a supporting portion 411 (e.g., a supporting seat or supporting shelf) to support a hardware component (e.g., the storage module 219 in FIG. 2A or “319” in FIG. 3A) or a portion of the hardware component, and a mounting portion 412 connected to (e.g., integrated with) the supporting portion 411.

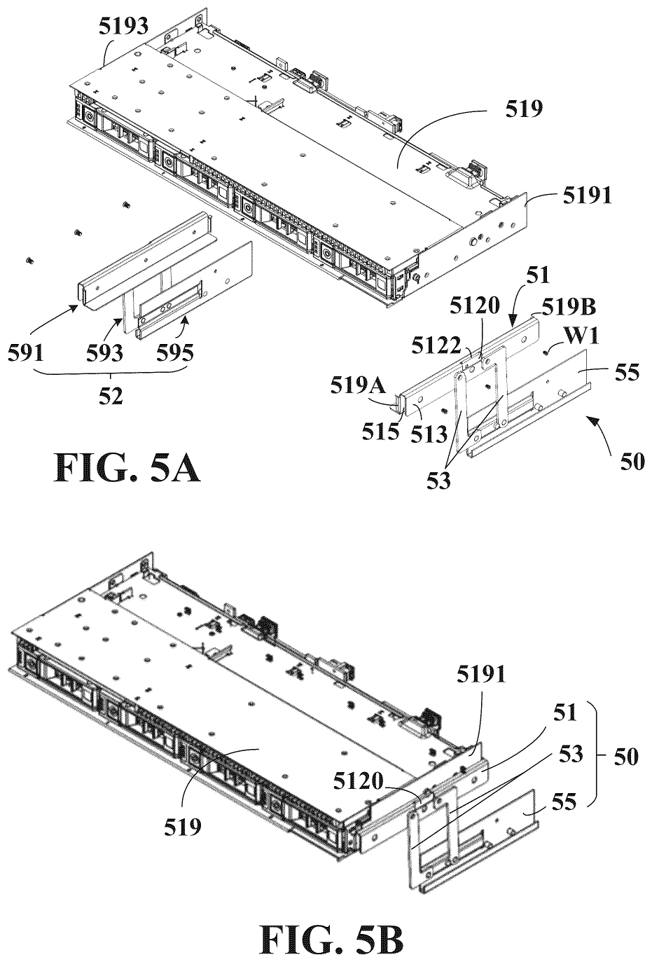

It is noted that the supporting component 41 (or the supporting component 51 in FIG. 5A) may sometimes be denoted in the present disclosure as “first supporting component” to differentiate “second supporting component” that may be included in a second linkage mechanism (see, e.g., “52” in FIG. 5A). Similarly, the connecting unit 43 in the first linkage mechanism may be sometimes denoted as “first connecting unit” to differentiate “second connecting unit” that may be included in the second linkage mechanism, and the fixation base 45 in the first linkage mechanism may be sometimes denoted as “first fixation base” to differentiate “second fixation base” that may be included in the second linkage mechanism. The terms “first” and “second” may be used in the present disclosure to distinguish a component from another, without limiting the components, and regardless of their importance and/or order. For example, a first supporting component and a second supporting component may indicate different supporting components that are included in different linkage mechanisms (e.g., the first linkage mechanism and the second linkage mechanism), despite that the first and second supporting components may have the same or similar configuration/structure. In some situations, a first component (e.g., first fixation base) may be denoted a second component (e.g., second fixation base), and vice versa, without departing from the scope of the present disclosure.

In some embodiments, a first supporting component (e.g., “41” in the first linkage mechanism 40, or “51” in FIG. 5A) and a second supporting component (e.g., “591” in the second linkage mechanism 52, see FIG. 5A) may have the same structure, mirrored structures, or different structures. In some embodiments, a first connecting unit (e.g., “43” in the first linkage mechanism 40, or “53” in FIG. 5A) and a second connecting unit (e.g., “593” in the second linkage mechanism 52) may have the same structure, mirrored structures, or different structures. In some embodiments, a first fixation base (e.g., “45” in the first linkage mechanism 40, or “55” in FIG. 5A) and a second fixation base (e.g., “595” in the second linkage mechanism, e.g., “52” in FIG. 5A) may have the same structure, mirrored structures, or different structures. As a non-limiting example, referring to FIG. 5A, the first fixation base 55 and the second fixation base 595 may have the same number of stopping members (e.g., “2” vs “2”), or different number of stopping members (e.g., “2” vs. “3”), that stop the first linkage mechanism 50 at a retracted position.

Referring to FIG. 4C, the mounting portion 412 may include, for instance, a first mounting plate 413, a second mounting plate 415, and a connecting portion 417 that connects the first mounting plate 413 with the second mounting plate 415. In some embodiments, the first mounting plate 413, the connecting portion 417, and the second mounting plate 415 may be integrated to form an inverse “U” shape, but this is not required.

In some embodiments, the connecting portion 417 may include a first connecting member 417a, a second connecting member 417b, and a third connecting member 417c, where the second connecting member 417b connects the first connecting member 417a with the third connecting member 417c. In some embodiments, the first connecting member 417a may connect the second mounting plate 415 with the second connecting member 417b, and the third connecting member 417c may connect the second connecting member 417b with the first mounting plate 413. In some embodiments, the first connecting member 417a, the second connecting member 417b, and the third connecting member 417c may be integrated to form an inverse “U” shape. In some embodiments, as seen in FIG. 4A and FIG. 4C, two legs of the inverse “U” shape formed by the connecting portion 417 may be shorter than two legs of the inverse “U” shape formed using the first mounting plate 413, the connecting portion 417, and the second mounting plate 415.

In some embodiments, the first connecting member 417a (and/or the third connecting member 417c) may have a bent shape or may include a flat portion. In some embodiments, the second connecting member 417b may be, or may include a flat portion that is parallel to a top surface of the supporting portion 411. In some embodiments, the supporting portion 411 may be connected to the second mounting plate 415 of the mounting portion 412, either directly or via a fourth connecting member (not shown).

In some embodiments, the first mounting plate 413 may include a plurality of through-holes. Referring to FIG. 4E, the plurality of through-holes of the first mounting plate 413 may include a first set of installation holes 413A and a set of connecting holes 413B (e.g., a first connecting hole A and a second connecting hole B, see in FIG. 4C). In some embodiments, referring to FIG. 4D, the second mounting plate 415 may include a plurality of through-holes, and the plurality of through-holes of the second mounting plate 415 may include a second set of installation holes 4150 that correspond to the first set of installation holes 413A, respectively. For example, as seen in FIG. 4C and FIG. 4E, the first set of installation holes 413A may include a first installation hole 4130a, a second installation hole 4130b, and a third installation hole 4130c. In this example, as seen in FIG. 4B and FIG. 4D, the second set of installation holes 4150 may include a fourth installation hole 4150a, a fifth installation hole 4150b, and a sixth installation hole 4150c.

The fourth installation hole 4150a at the second mounting plate 415 may correspond to the first installation hole 4130a at the first mounting plate 413. The fifth installation hole 4150b at the second mounting plate 415 may correspond to the second installation hole 4130b at the first mounting plate 413. The sixth installation hole 4150c at the second mounting plate 415 may correspond to the third installation hole 4130c at the first mounting plate 413. In some embodiments, a size of a respective installation hole (e.g., 4130a) at the first mounting plate 413 may be greater than a size of a respective installation hole (e.g., 4150a) at the second mounting plate 415 that corresponds to the respective installation hole (e.g., 4130a) at the first mounting plate 413. In this way, a penetration end (e.g., a threaded portion) of a fixation element (e.g., a screw) can traverse through the respective installation hole (e.g., 4130a) at the first mounting plate 413 and the corresponding installation hole (e.g., 4150a) at the second mounting plate 415 sequentially. The smaller size of the respective installation hole 4150a may allow the second mounting plate 415 to be more tightly secured using the fixation element.

In some embodiments, referring again to FIG. 4A and FIG. 4B, the mounting portion 412 may include an opening portion 4120 that enables one or more human fingers (or a mechanical tool) to insert and grab a finger-grab portion (shortly as “finger-grab”) 4122 of the second connecting member 417b. In some embodiments, referring to FIG. 4C, the first mounting plate 413 may include a first opening 4131. Additionally, or alternatively, the third connecting member 417c may include a second opening 4171. In some embodiments, the first opening 4131 and the second opening 4171 may be connected to each other, to form the opening portion 4120. In some embodiments, the opening portion 4120 may include, but does not necessarily need to include, a third opening 4191 at the second connecting member 417b. In some embodiments, the first opening 4131 of the first mounting plate 413 may be located above the second installation hole 4130b (which is from the first set of installation holes 413A). In some embodiments, the first opening 4131 may have a rectangular shape, a rounded rectangular shape, or any other applicable shape or size. For example, referring to FIG. 4A and FIG. 4C, the first opening 4131 may include a first side S1 and a second side S2 opposite to the first side S1. As a non-limiting example, the first side S1 may extend in a direction intersecting a line that connects a center of the first connecting hole A and a center of the second installation hole 4130b, and the second side S2 may extend in a direction intersecting a line that connects a center of the second connecting hole B and the center of the second installation hole 4130b.

In some embodiments, as shown in FIG. 4C, the supporting component 41 and the second mounting plate 415 may form an L-shaped shelf to hold or support, e.g., the storage module 219. In some embodiments, the first linkage mechanism 40, or the L-shaped shelf, may further include one or more blocking portions. For example, referring to FIGS. 4A, 4B, and 4D, the first linkage mechanism 40 may include a first blocking portion 419A and a second blocking portion 419B. The first blocking portion 419A, the supporting component 41, and/or the second blocking portion 419B may be configured to fix (or limit) a position of a module (e.g., the storage module 219 or other component) that the L-shaped shelf supports. In some embodiments, as seen in FIG. 4A, the first blocking portion 419A and/or the second blocking portion 419B may be perpendicular to a top surface (or a bottom surface) of the supporting component 41. In some embodiments, the first blocking portion 419A and/or the second blocking portion 419B may be flexible and can be deformed to facilitate placement or removal of the module (e.g., the storage module 219 or other component) onto or from the L-shaped shelf.

In some embodiments, referring to FIGS. 4A˜4C and 4F, the first linkage member 43A (“driving linkage member”) may include a first body portion 431 and a first end portion 433. In some embodiments, the first body portion 431 may be integrated with the first end portion 433, e.g., to form an L-shape. In some embodiments, an axis (“X1” in FIG. 4A) of the first body portion 431 and an axis (e.g., “X2” in FIG. 4A) of the first end portion 433 may form a first angle, where the first angle can be (but does not necessarily need to be) approximately 90°. In some embodiments, as seen in FIG. 4B, the first body portion 431 may include a first pivoting-connection hole 4311 for connection to the fixation base 45, and the first end portion 433 may include a first pivoting hole 4331 that enables a first fixation element (e.g., a first screw) to pass through. In some embodiments, referring to FIG. 4F, the first body portion 431 may include a stop notch 4310 configured to stop pivoting/rotation of the first linkage member 43A (and therefore the first linkage mechanism 40 that contains the first linkage member 43A) with respect to the first pivoting-connection hole 4311. In some embodiments, referring to FIG. 4B, the first pivoting hole 4331 of the first linkage member 43A may be aligned with the second connecting hole B of the first mounting plate 413, for a threaded portion of the first screw to advance through, thereby engaging the first linkage member 43A with the first mounting plate 413.

In some embodiments, referring to FIG. 4C, the second linkage member 43B may include a second body portion 432 and a second end portion 434. In some embodiments, the second body portion 432 may be integrated with the second end portion 434, e.g., to form an L-shape. In some embodiments, an axis (“X3” in FIG. 4C) of the second body portion 432 and an axis (“X4” in FIG. 4C) of the second end portion 434 may form a second angle, where the second angle can be but does not necessarily need to be approximately 90°. In some embodiments, further referring to FIG. 4C, the second body portion 432 may include a second pivoting hole 4321 that enables a second fixation element (e.g., a second screw) to pass through, and the second end portion 434 may include a second pivoting-connection hole 4341 for connection to the fixation base 45. In some embodiments, referring to FIG. 4B, the second pivoting hole 4321 of the second linkage member 43B may be aligned with the first connecting hole A of the first mounting plate 413, for a threaded portion of the second screw to advance through, thereby engaging the second linkage member 43B with the first mounting plate 413.

In some embodiments, as seen in FIG. 4C, the fixation base 45 may include a connecting plate 451 and a buffering structure 453. In some embodiments, the connecting plate 451 may include a plate region 4510 and a protruding region 4512 that protrudes from the plate region 4510. In some embodiments, the protruding region 4512 may include a first protruding shaft member P1 to engage with the second pivoting-connection hole 4341 at the second end portion 434 of the second linkage member 43B. In some embodiments, the protruding region 4512 may include a second protruding shaft member P2 to engage with the first pivoting-connection hole 4311 that is at the first body portion 431 of the first linkage member 43A.

In some embodiments, further referring to FIG. 4C, the protruding region 4512 may include a first protruding stopping element (e.g., a stopping shaft SS) to engage with the stop notch 4310 of the first body portion 431 of the first linkage member 43A. In some embodiments, after the first pivoting-connection hole 4311 engages with the second protruding shaft member P2, the first body portion 431 of the first linkage member 43A may rotate around the second protruding shaft member P2, e.g., in a clockwise direction or an anti-clockwise direction. In this case, as shown in FIG. 4A and FIG. 4B, the first body portion 431 of the first linkage member 43A may stop rotation (e.g., in an anti-clockwise direction) in response to the stopping shaft SS being engaged with the stop notch 4310. In some embodiments, as seen in FIG. 4C and FIG. 4G, the stopping shaft SS may be disposed between the first protruding shaft member P1 and the second protruding shaft member P2. In some embodiments, referring to FIG. 4B, the first protruding shaft member P1, the stopping shaft SS, and the second protruding shaft member P2 may be disposed along a straight line L1. In some embodiments, a line connecting the first protruding shaft member P1 and the stopping shaft SS may intersect with a line connecting the stopping shaft SS and the second protruding shaft member P2.

In some embodiments, referring to FIG. 4C, the plate region 4510 of the connecting plate 451 may include one or more stopping members to stop rotation of the first linkage member 43A in a clockwise direction. The first linkage member 43A may be stopped at a retracted position using the one or more stopping members. In some embodiments, the one or more stopping members that stop the first linkage member 43A at the retracted position may include a first stopping member M1 and a second stopping member M2. However, the total number of the one or more stopping members is not limited to “2” and can be any applicable number.

In some embodiments, one or more of the first protruding stopping element (e.g., “SS” in FIG. 4C), the first stopping member M1, and/or the second stopping member M2 may have a columnar structure. In some embodiments, along a direction (“x-axis”) that is substantially perpendicular to the plate region 4510 of the connecting plate 451, a length of the first stopping member M1 (or the second stopping member M2) may be the same as, or greater than a length of the first protruding stopping element SS. In some embodiments, a line L2 connecting the first stopping member M1 and the second stopping member M2 may be parallel to the line L1 that connects the first protruding shaft member P1 and the second protruding shaft member P2. In some embodiments, referring to FIG. 4B, there is a predefined distance D between the line L1 and the line L2, such that the first body portion 431 of the first linkage member 43A may rest horizontally (see in FIG. 4H or 41) when the first linkage member 43A is at the retracted position.

In some embodiments, referring to FIG. 4C, the buffering structure 453 of the fixation base 45 may be integrated with the connecting plate 451. In some embodiments, the buffering structure 453 may include a first portion 4531 and/or a second portion 4533. In some embodiments, the first portion 4531 may be, or may include, a bottom plate, and the second portion 4533 may be, or may include, a sidewall, where the bottom plate and the sidewall form an L shape. In some embodiments, the buffering structure 453 may include a protruding block that protrudes from the connecting plate 451. In some embodiments, the protruding block (or the second portion 4533) may be configured to support the first stopping member M1 and/or the second stopping member M2, but this is not required.

In some embodiments, a width of the first portion 4531 (of the buffering structure 453) along the direction of “x-axis” (see in FIG. 4C) may be customized to ensure sufficient space or distance between the plate region 4510 of the connecting plate 451 and a server chassis (e.g., “400” in FIG. 4J, or any other applicable structure) to which the first linkage mechanism 40 is to be mounted or attached. In some embodiments, the second portion 4533 of the buffering structure 453 may be covered with a protective layer (e.g., made of protective film, a flexible material, or a deformable material) to provide a buffering effect. In some embodiments, the plate region 4510 of the connecting plate 451 may include one or more holes (e.g., “457” in FIG. 4C) for attaching or securing the fixation base 45 to the server chassis (or any other structure) to which the first linkage mechanism 40 is to be mounted or attached.

FIG. 4J illustrates a perspective view of a lifting device having the first linkage mechanism in FIG. 4A in the first position. FIG. 4K illustrates a perspective view of a lifting device having the first linkage mechanism in FIG. 4A in the second position. FIG. 4L illustrates a top view of the lifting device with the first linkage mechanism in the first position and the second position, respectively.

Referring to FIG. 4J and FIG. 4K, a lifting device may include the first linkage mechanism 40 and a second linkage mechanism 42. In some embodiments, the first linkage mechanism 40 and the second linkage mechanism 42 are mirrored structures. In some embodiments, the fixation base 45 (not shown in FIG. 4J and FIG. 4K) of the first linkage mechanism 40 may be attached (e.g., removably attached or fixedly attached) to a first side portion 403 of a chassis 400. In some embodiments, a fixation base (not shown) of the second linkage mechanism 42 may be attached (e.g., removably attached or fixedly attached) to the second side portion 405 of the chassis 400, where the second side portion 405 is opposite to the first side portion 403.

In some embodiments, the first supporting component 41 of the first linkage mechanism 40 and the second supporting component (not shown) of the second linkage mechanism 42 may be configured to support a hardware component (e.g., storage module 418). In some embodiments, the one or more blocking portions (e.g., 419A and/or 419B) of the first linkage mechanism 40 and one or more blocking portions of the second linkage mechanism 42 may be configured to fix (or limit) a position of the hardware component (e.g., storage module 418) that the first supporting component 41 of the first linkage mechanism 40 and the second supporting component (not shown) of the second linkage mechanism 42 support.

In some embodiments, referring to FIG. 4K and scenario (a) in FIG. 4L, the lifting device (e.g., the first linkage mechanism 40 and the second linkage mechanism 42) may be at a retracted position. For example, the lifting device may be at the retracted position when the chassis 400 is covered using a top cover. As shown in FIG. 4I, at the retracted position, a distance between an axis “X1” of the first body portion 431 of the first linkage member 43A and an axis “X3” of the second body portion 432 of the second linkage member 43B may be denoted as “d1.” The distance “d1” may be less than a distance (denoted by “d2,” see in FIG. 4B) between the axis of the first body portion 431 and the axis of the second body portion 432 when the lifting device is at the lifted position.

In some embodiments, as mentioned earlier, the mounting portion 412 of the supporting component 41 of the first linkage mechanism 40 may have an inverse “U” shape. Referring to FIG. 4H, when the lifting device is at the retracted position, a portion of the connecting plate 451 (e.g., the plate region 4510) of the fixation base 45 may be inserted into a cavity 416 created by the inverse “U” shape of the mounting portion 412. This allows an overall thickness of the first linkage mechanism 40 (or the second linkage mechanism 42) to be reduced, so that less space of the chassis 400 is occupied by the lifting device. In some embodiments, at the retracted position, a portion of the first end portion 433 of the first linkage member 43A and a portion of the second body portion 432 of the second linkage member 43B may be inserted into the cavity 416. But this is not required. For example, as shown in FIG. 4H, in some embodiments, the first linkage member 43A and the second linkage member 43B may be attached to an outer surface of the first mounting plate 413 of the mounting portion 412 of the first linkage mechanism 40.

Referring to FIG. 4J and scenario (b) in FIG. 4L, the lifting device may be at the lifted position to expose a region R that would otherwise be covered or partially covered by the storage module 219 (or any other applicable module or component supported by the lifting device). When the lifting device is at the lifted position, components installed within the region R may be accessed conveniently, which facilitate any maintenance operation or replacement operation of one or more components (e.g., a CPU, a memory module, etc.) placed or installed within the region R.

FIG. 5A and FIG. 5B illustrate a process for attaching a lifting device to a hardware module, according to one or more embodiments of the present disclosure. As shown in FIG. 5A, a first linkage mechanism 50 may be attached to (e.g., removably attached to) a first side plate 5191 of a storage module 519, and a second linkage mechanism 52 may be attached to (e.g., removably attached to) a second side plate 5193 of the storage module 519. The first linkage mechanism 50 in FIG. 5A or FIG. 5B may be the same as, or similar to, the aforementioned first linkage mechanism 40, and the second linkage mechanism 52 in FIG. 5A or FIG. 5B may be the same as, or similar to, the aforementioned second linkage mechanism 42. Repeated descriptions are omitted herein for the sake of brevity.

As shown in FIG. 5A, prior to attaching the first linkage mechanism 50 to the storage module 519, the first linkage mechanism 50 may be configured at the lifted position. While the first linkage mechanism 50 is at the lifted position, the first side plate 5191 of the storage module 519 may be placed onto the L-shaped shelf (e.g., formed by a first supporting component 51 and the second mounting plate 515 of the first linkage mechanism 50). In some embodiments, the one or more blocking portions (e.g., 519A and 519B) of the first linkage mechanism 50 may be configured to ensure a position of the storage module 519 on the L-shaped shelf is fixed with respect to a second mounting plate 515 of the linkage mechanism 50. In this way, mounting/installation hole(s) of the first mounting plate 513 of the linkage mechanism 50 may be aligned with mounting/installation hole(s) at the second mounting plate 515 (and/or with hole(s) at connecting unit 53 of the first linkage mechanism 50), which allows a first set of screws (“W1”) to be applied to attach the first supporting component 51 of the first linkage mechanism 50 to the first side plate 5191 of the storage module 519. Similarly, a second supporting component of the second linkage mechanism 52 may be attached to the second side plate 5193 of the storage module 519. Repeated descriptions are omitted herein.

In some embodiments, referring to FIG. 5B, a lifted position of the storage module 519 after being attached to the lifting device (which includes the first linkage mechanism 50 and/or the second linkage mechanism 52) is provided. A user may grab a first finger-grab portion 5122 of the first linkage mechanism 50 (and/or grab a second finger-grab portion (not shown) of the second linkage mechanism 52) to move the lifting device from the lifted position shown in FIG. 5B to a retracted position (not shown in FIG. 5B), or vice versa.

In some embodiments, referring back to FIG. 4J and FIG. 4K which respectively show a lifted position and a retracted position of a lifting device, to lift the lifting device when the lifting device is attached to a storage enclosure (e.g., the chassis 400), a user may pull a front portion 422 of the storage module 418, or push a rear portion 424 of the storage module 418, to raise the lifting device (e.g., at an intermediate position). In some embodiments, the user can further pull (e.g., the front portion 422) or push (e.g., the rear portion 424) the storage module 418 to transition the lifting device (e.g., the first linkage mechanism 40 and/or the second linkage mechanism 42) from the intermediate position to the lifted position. When the lifting device is at the lifted position (or at the intermediate position), the user may grab the lifting device through the opening portion 4120 (see in FIG. 4A) to move the lifting device from the lifted position (or the intermediate position) back to the retracted position.

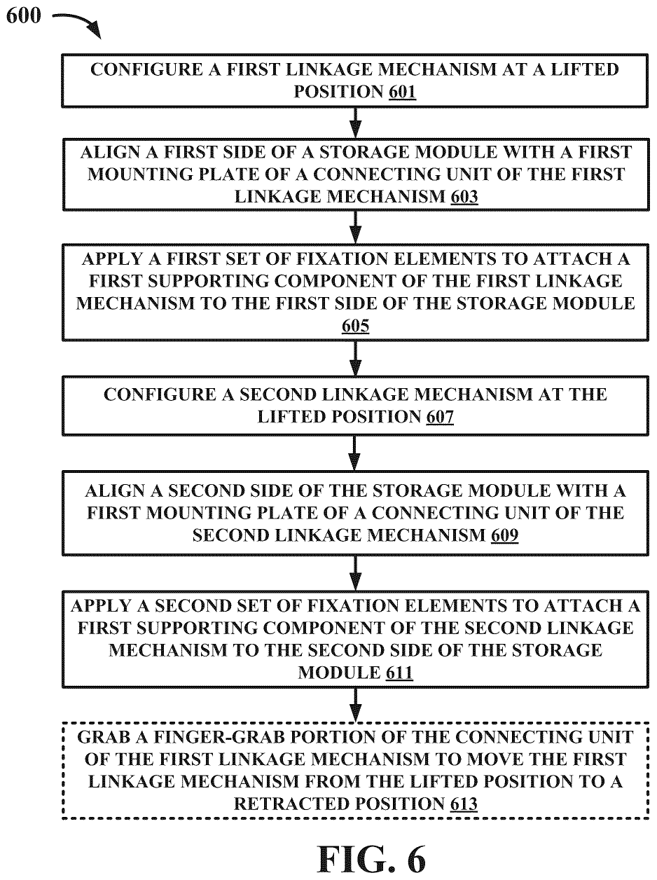

FIG. 6 illustrates a method for mounting a storage module to a lifting device, according to one or more embodiments of the present disclosure. While operations of the method 600 are shown in a particular order, this is not meant to be limiting. One or more operations may be reordered, omitted, and/or added except where otherwise apparent. In various embodiments, as shown in FIG. 6, the method 600 includes, at stage 601, configuring a first linkage mechanism (e.g., “40” in FIG. 4A, or “50” in FIG. 5A) at a lifted position, where the first linkage mechanism includes a first supporting component (e.g., “41” in FIG. 4A, or 51 in FIG. 5A), a connecting unit (e.g., “43” in FIG. 4A, or “53” in FIG. 5A), and a fixation base (e.g., “45” in FIG. 4A, or “55” in FIG. 5A). The first supporting component may be configured to support the storage module (or a portion thereof). The connecting unit may include a first linkage member (e.g., “43A” in FIG. 4A) and/or a second linkage member (e.g., “43B” in FIG. 4A). A body portion (e.g., “431” in FIG. 4A) of the first linkage member may be configured to rotate around a protruding shaft member (e.g., “P2” in FIG. 4C) disposed at the fixation base, and an end portion (e.g., “433” in FIG. 4A) of the first linkage member may be configured to connect with the first supporting component.

In some embodiments, the fixation base (e.g., 45) may include a first group of stopping structures (e.g., “SS”) that stop the first linkage member (e.g., 43A) at a first position (e.g., a lifted position). Additionally, or alternatively, the fixation base (e.g., 45) may include a second group of stopping structures (e.g., “M1” and/or “M2”) that stop the first linkage member (e.g., 43A) at a second position (e.g., a retracted position).

In some embodiments, the first group of stopping structures of the fixation base may include a first protruding stopping element (e.g., the stopping shaft SS in FIG. 4C) to engage with a stopping notch (e.g., “4310” in FIG. 4C) of the body portion of the first linkage member. The first linkage mechanism can be stopped/configured at the lifted position in response to the first protruding stopping element of the fixation base being engaged with the stopping notch of the body portion of the first linkage member. In some embodiments, the second group of stopping structures of the fixation base may include one or more stopping members (e.g., “M1” and/or “M2” in FIG. 4C) to stop/configure the first linkage mechanism at the retracted position. In some embodiments, the first linkage mechanism may be rotated in an anti-clockwise direction to switch from the retracted position to the lifted position. In some embodiments, the first linkage mechanism may be rotated in a clockwise direction to switch from the lifted position to the retracted position.

In some embodiments, the connecting unit of the first linkage mechanism may include an opening (e.g., 4120 in FIG. 4A) for a user to grab a finger-grab portion (e.g., “4122” in FIG. 4A) of the connecting unit.

In various embodiments, as shown in FIG. 6, the method 600 includes, at stage 603, aligning a first side (e.g., “first side plate 203” in FIG. 2B) of a storage module (e.g., having one or more HDDs, or other hardware module or component) with a first mounting plate (e.g., “413” in FIG. 4C) of the connecting unit of the first linkage mechanism. In some embodiments, the fixation base of the first linkage mechanism may be connected (e.g., fixedly or removably attached) to a first inner wall (e.g., opposite to the “first side plate 203” in FIG. 2B) of a storage enclosure.

In various embodiments, as shown in FIG. 6, the method 600 includes, at stage 605, applying a first set of fixation elements (e.g., screw(s), not depicted) to attach the first supporting component of the first linkage mechanism to the first side of the storage module.

In various embodiments, as shown in FIG. 6, the method 600 includes, at stage 607, configuring a second linkage mechanism (e.g., “52” in FIG. 5A) at a lifted position, where the second linkage mechanism and the first linkage mechanism are mirrored structures or substantially mirrored (e.g., other than a difference in the total number of stopping members, etc.). In some embodiments, a fixation base (may also be referred to as a “second fixation base”) of the second linkage mechanism may be connected (e.g., fixedly or removably attached) to a second inner wall of the storage enclosure, where the second inner wall of the storage enclosure is opposite to the first inner wall of the storage enclosure.

In various embodiments, as shown in FIG. 6, the method 600 includes, at stage 609, aligning a second side (e.g., a second side plate) of the storage module with a first mounting plate of a connecting unit of the second linkage mechanism.

In various embodiments, as shown in FIG. 6, the method 600 includes, at stage 611, applying a second set of fixation elements (e.g., screw(s)) to attach a supporting component (may also be referred to as “a second supporting component” to differentiate from the “first supporting component” in the first linkage mechanism) of the second linkage mechanism to the second side of the storage module.

It is noted that, the terms “first” and “second” are used herein to distinguish a component from another, without limiting the components, and regardless of their importance and/or order. For example, a first supporting component and a second supporting component may indicate different supporting components from each other and be included in different linkage mechanisms (e.g., the first linkage mechanism and the second linkage mechanism). The first supporting component and the second supporting component may have the same structure, mirrored structures, or different structures.

In various embodiments, as shown in FIG. 6, the method 600 includes, at stage 613, grabbing at least the finger-grab portion (e.g., “4122” in FIG. 4A) of the connecting unit of the first linkage mechanism (and/or a finger-grab portion of a connecting unit of the second linkage mechanism) to move the first linkage mechanism (and therefore the second linkage mechanism) from the lifted position to the retracted position. In some embodiments, at stage 613, a finger-grab portion of a connecting unit of the second linkage mechanism may be grabbed to facilitate movement of the first linkage mechanism (and/or the second linkage mechanism) from the lifted position to the retracted position.

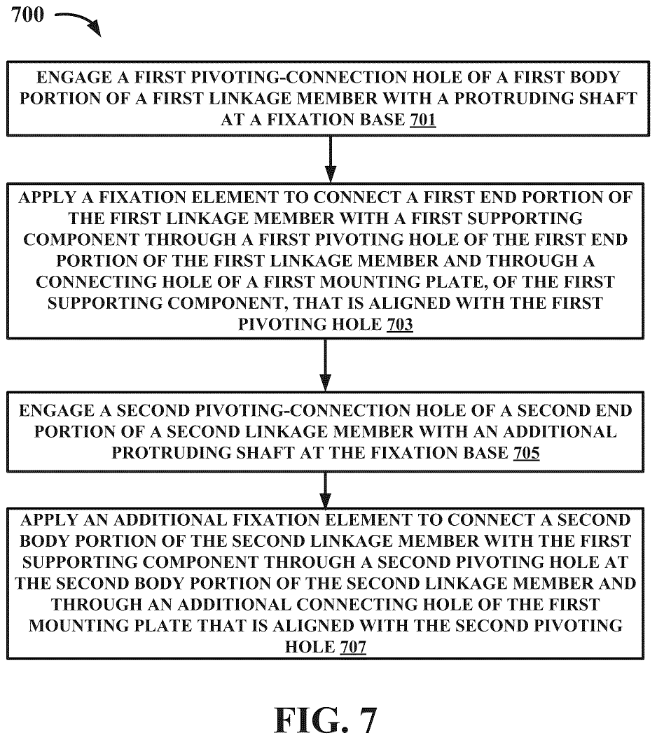

FIG. 7 illustrates a method 700 for assembling a first linkage mechanism, according to one or more embodiments of the present disclosure. While operations of the method 700 are shown in a particular order, this is not meant to be limiting. One or more operations may be reordered, omitted, and/or added except where otherwise apparent.

In various embodiments, as shown in FIG. 7, the method 700 includes, at stage 701, engaging a first pivoting-connection hole (e.g., “4311” in FIG. 4C) of a first body portion (e.g., “431” in FIG. 4B) of a first linkage member with a protruding shaft (e.g., the aforementioned “second protruding shaft member P2”) at a fixation base.

In various embodiments, as shown in FIG. 7, the method 700 includes, at stage 703, applying a fixation element (e.g., a screw “W1” in FIG. 5A) to connect a first end portion (e.g., “433” in FIG. 4B) of the first linkage member with a supporting component through a first pivoting hole (e.g., “4331” in FIG. 4C) of a first end portion of the first linkage member and through a connecting hole (e.g., “second connecting hole B” in FIG. 4C) of a first mounting plate (of the supporting component) that is aligned with the first pivoting hole.

In various embodiments, as shown in FIG. 7, the method 700 includes, at stage 705, engaging a second pivoting-connection hole (e.g., “4341” in FIG. 4C) of a second end portion of a second linkage mechanism with an additional protruding shaft (e.g., the aforementioned “first protruding shaft member P1”) at the fixation base.

In various embodiments, as shown in FIG. 7, the method 700 includes, at stage 707, applying an additional fixation element (e.g., a screw) to connect a second body portion of the second linkage member with the supporting component through a second pivoting hole (e.g., “4321” in FIG. 4C) at the second body portion of the second linkage member and through an additional connecting hole (e.g., “first connecting hole A” in FIG. 4C) of the first mounting plate that is aligned with the second pivoting hole.

In some embodiments, the fixation base includes a stopping shaft (“SS”) to engage with a stop notch (e.g., 4310 in FIG. 4C) of the first body portion of the first linkage member, such that when the first linkage mechanism rotates in an anti-clockwise direction, the first linkage mechanism may be stopped at a lifted position. In some embodiments, the fixation base includes one or more stopping members (e.g., “M1” and/or “M2”), such that when the first linkage mechanism rotates in a clockwise direction, the first linkage mechanism may be stopped at a retracted position, without crashing into other components (e.g., CPU, memory module) that is located below a hardware component (e.g., storage module) which is carried by a lifting device having the first linkage mechanism and/or a second linkage mechanism.

It is to be understood that the foregoing is presented by way of example only and that, within the scope of the appended claims and equivalents thereto, embodiments or implementations may be practiced otherwise than as specifically described and claimed. Embodiments of the present disclosure are directed to each individual feature, system, and/or method described herein. In addition, any combination of two or more such features, systems, and/or methods, if such features, systems, and/or methods are not mutually inconsistent, is included within the scope of the present disclosure.

In various embodiments, a linkage mechanism is provided. The linkage mechanism may be the same as, or similar to, the “first linkage mechanism 40” in FIG. 4A. The linkage mechanism may include: a supporting component, a connecting unit, and/or a fixation base. The connecting unit may include a first linkage member movable between a lifted position and a retracted position. The linkage member may include a first body portion to connect with the fixation base and a first end portion to connect with the first supporting component.

In some embodiments, the fixation base includes a first protruding stopping element to stop the first linkage member at the lifted position. In some embodiments, the first body portion of the first linkage member may include a stop notch to engage with the first protruding stopping element. In some embodiments, the fixation base may include a plate region and a protruding region that protrudes from the plate region. In some embodiments, the first protruding stopping element that is configured to stop the first linkage member at the lifted position may be disposed on the protruding region of the fixation base.

In some embodiments, the fixation base may additionally, or alternatively, include one or more stopping members to stop the first linkage member at the retracted position. In some embodiments, the one or more stopping members may be disposed on the plate region of the fixation base.

In some embodiments, the supporting component may include an opening portion that provides access to a finger-grab portion of the supporting component.

In some embodiments, the fixation base may include a first protruding shaft member to engage with a first pivoting-connection hole that is at the first body portion of the first linkage member, thereby enabling the first body portion to be connected with the fixation base. In some embodiments, the first protruding shaft member may be disposed on the fixation base, e.g., in proximity to the first protruding stopping element.

In some embodiments, the connecting unit may include a second linkage member configured to move in response to the first linkage member being moved. In some embodiments, the second linkage member may include a second body portion and a second end portion. In some embodiments, the second body portion of the second linkage member may be integrated with the second end portion of the second linkage member to form approximately an L shape.

In some embodiments, the fixation base may include a second protruding shaft member to engage with a second pivoting-connection hole that is at the second end portion of the second linkage member, thereby enabling the second end portion of the second linkage member to connect with the fixation base.

In some embodiments, the first body portion of the first linkage member is integrated with the first end portion of the first linkage member to form approximately an L shape.

In some embodiments, the first end portion of the first linkage member may include a first pivoting hole that corresponds to an installation hole at a first mounting plate of the supporting component.

In some embodiments, the supporting component may include the first mounting plate and a second mounting plate. In some embodiments, the second mounting plate may include an additional installation hole corresponding to the installation hole at the first mounting plate of the supporting component. In some embodiments, the additional installation hole at the second mounting plate may be smaller than the installation hole at the first mounting plate, to facilitate fastening of a fixation element (e.g., a screw) to the second mounting plate, where the fixation element may be applied to connect the supporting component with the connecting unit and/or with a storage module that is supported by the supporting component. The storage module may be placed or supported by a supporting shelf or a supporting seat of the supporting component.

The linkage mechanism (or a lifting device containing the linkage mechanism) can be attached to the storage enclosure (e.g., a chassis for an electronic system such as a server), e.g., using one or more fixation elements. The configuration of the linkage mechanism according to one or more embodiments may allow convenient access to one or more components (e.g., one or more processors and/or one or more memory modules), e.g., that are stored within the storage enclosure and that are stacked below the storage module, without having to detach the linkage mechanism from the storage enclosure. For example, the linkage mechanism (e.g., the supporting component) can be lifted to the lifted position to lift the storage module, thereby exposing the one or more components (e.g., stacked below the storage module) that need to be accessed, repaired, replaced, etc. The linkage mechanism may also be configured at the retracted position, such that the storage enclosure can be, for instance, sealed or covered with a top cover.

In some embodiments, as described above, the linkage mechanism may include a supporting shelf or a supporting seat. The supporting shelf or the supporting seat may be capable of supporting one or more additional components (e.g., the aforementioned storage module having one or more HDDs or SSD, or other applicable component or module) for the electronic system. The one or more additional components (e.g., HDDs) may be lifted in response to the linkage mechanism being lifted to the lifted position (or an intermediate position between the lifted position and the retracted position). In some embodiments, the one or more additional components may be fixedly or removably attached to the linkage mechanism. In the case where the one or more additional components (e.g., HDDs) are removably attached to the linkage mechanism, the one or more additional components may be removed (in addition to being lifted) to further expose: the one or more processors and/or one or more memory modules which would otherwise be stored/stacked below the supporting shelf (and the one or more additional components supported by the supporting shelf) when the linkage mechanism is at the retracted position. In this way, access to the one or more processors and/or one or more memory modules may be facilitated.

In various embodiments, a lifting device is provided. The lifting device may include: a first linkage mechanism. The first linkage mechanism may include: a connecting unit, and a fixation base. In some embodiments, the connecting unit may include a first linkage member movable between a lifted position and a retracted position. In some embodiments, the first linkage member may include a first body portion to connect with the fixation base. In some embodiments, the first linkage mechanism may further include a supporting component. In some embodiments, the first linkage member includes a first end portion to connect with the supporting component.

In some embodiments, the lifting device may further include a second linkage mechanism. In some embodiments, the first and second linkage mechanisms may have mirrored structures. In some embodiments, the first and second linkage mechanisms may have different structures.

In various embodiments, a linkage mechanism is provided. The linkage mechanism may include: a fixation base, and a first linkage member comprising a stop notch. In some embodiments, the fixation base may include a first protruding stopping element to engage with the stop notch of the first linkage member, so as to stop the first linkage member at a lifted position.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the terms such as “and/or” (for example, “A and/or B”), or “at least one” followed by a list of one or more items (for example, “at least one of A and B”), are to be construed to mean one item selected from the listed items (A or B) or any combination of two or more of the listed items (A and B), unless otherwise indicated herein or clearly contradicted by context. The terms “approximately” or “substantially” are meant to cover any normal fluctuations or deviations (e.g., ±20% or other applicable deviation percentages or degrees) appreciated by one of ordinary skill in the relevant art. The terms “comprising,” “having,” “including,” and “containing” are to be construed as open-ended terms (i.e., meaning “including, but not limited to,”) unless otherwise noted. Recitations of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Exemplary embodiments are described herein. Variations of those exemplary embodiments may become apparent to those of ordinary skill in the art upon reading the foregoing description. It is understood that skilled artisans are able to employ such variations as appropriate, and the invention may be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A linkage mechanism, comprising:
a supporting component;
a connecting unit; and
a fixation base,
wherein the connecting unit comprises a first linkage member movable between a lifted position and a retracted position, and
wherein the first linkage member comprises a first body portion to connect with the fixation base and a first end portion to connect with the supporting component.

2. The linkage mechanism of claim 1, wherein the fixation base comprises a first protruding stopping element to stop the first linkage member at the lifted position.

3. The linkage mechanism of claim 2, wherein the first body portion of the first linkage member comprises a stop notch to engage with the first protruding stopping element.

4. The linkage mechanism of claim 2, wherein the fixation base comprises a plate region and a protruding region that protrudes from the plate region portion, and wherein the first protruding stopping element to stop the first linkage member at the lifted position is disposed on the protruding region of the fixation base.

5. The linkage mechanism of claim 4, wherein the fixation base comprises one or more stopping members to stop the first linkage member at the retracted position, the one or more stopping members being disposed on the plate region of the fixation base.

6. The linkage mechanism of claim 1, wherein the supporting component comprises an opening portion that provides access to a finger-grab portion of supporting component.

7. The linkage mechanism of claim 1, wherein the fixation base comprises a first protruding shaft member to engage with a first pivoting-connection hole that is at the first body portion of the first linkage member, thereby enabling the first body portion to connect with the fixation base.

8. The linkage mechanism of claim 7, wherein the first protruding shaft member is disposed on the fixation base in proximity to a first protruding stopping element.

9. The linkage mechanism of claim 1, wherein the connecting unit further comprises a second linkage member configured to move in response to the first linkage member being moved.

10. The linkage mechanism of claim 9, wherein the second linkage member comprises a second body portion and a second end portion.

11. The linkage mechanism of claim 10, wherein the second body portion of the second linkage member is integrated with the second end portion of the second linkage member to form approximately an L shape.

12. The linkage mechanism of claim 10, wherein the fixation base comprises a second protruding shaft member to engage with a second pivoting-connection hole that is at the second end portion of the second linkage member, thereby enabling the second end portion of the second linkage member to connect with the fixation base.

13. The linkage mechanism of claim 1, wherein the first body portion of the first linkage member is integrated with the first end portion of the first linkage member to form approximately an L shape.

14. The linkage mechanism of claim 1, wherein the first end portion of the first linkage member comprises a first pivoting hole that corresponds to an installation hole at a first mounting plate of the supporting component.

15. The linkage mechanism of claim 14, wherein the supporting component comprises the first mounting plate and a second mounting plate, and wherein the second mounting plate comprises an additional installation hole corresponding to the installation hole at the first mounting plate of the supporting component.

16. The linkage mechanism of claim 15, wherein the additional installation hole at the second mounting plate is smaller than the installation hole at the first mounting plate.

17. A lifting device, comprising:
a first linkage mechanism,
wherein the first linkage mechanism comprises:
a connecting unit, and
a fixation base,
wherein the connecting unit comprises a first linkage member movable between a lifted position and a retracted position, and
wherein the first linkage member comprises a first body portion to connect with the fixation base.

18. The lifting device of claim 17, wherein the first linkage mechanism further comprises:
a supporting component,
wherein the first linkage member further comprises a first end portion to connect with the supporting component.

19. The lifting device of claim 17, further comprising:
a second linkage mechanism,
wherein the first and second linkage mechanisms have mirrored structures.

20. A linkage mechanism, comprising:
a fixation base, and
a first linkage member comprising a stop notch,
wherein the fixation base comprises a first protruding stopping element to engage with the stop notch of the first linkage member, so as to stop the first linkage member at a lifted position.
